(19) United States
(12) Patent Application Publication
(10) Pub. No.: US 2011/0074020 A1
(43) Pub. Date: Mar. 31, 2011

(54) SEMICONDUCTOR DEVICE AND METHOD FOR MOUNTING SEMICONDUCTOR DEVICE

(75) Inventors: Takatoyo YAMAKAMI, Kawasaki (JP); Takashi KUBOTA, Kawasaki (JP); Hidehiko KIRA, Kawasaki (JP); Takayoshi MATSUMURA, Kawasaki (JP)

(73) Assignee: FUJITSU LIMITED, Kawasaki-shi (JP)

(21) Appl. No.: 12/892,031

(22) Filed: Sep. 28, 2010

(30) Foreign Application Priority Data
Sep. 30, 2009 (JP) 2009-227400

(51) Int. Cl. H01L 23/498; H01L 21/50

(52) U.S. Cl. 257/737; 438/106; 257/E21.499; 257/E23.069

(57) ABSTRACT

A method for mounting a semiconductor device by mounting a semiconductor chip on a board by flip chip bonding, comprising: contacting an Au bump of the semiconductor chip with a Sn—Bi solder; and heating the Sn—Bi solder at a temperature which is not lower than the melting point thereof and which is not higher than 180° C. for 30 minutes or more.

### CROSS REFERENCE TO RELATED APPLICATION

This application is based upon and claims the benefit of priority from the prior Japanese Patent Application NO. 2009-227400 filed on Sep. 30, 2009, the entire contents of which are incorporated herein by reference.

### FIELD

The embodiments discussed herein are related to a semiconductor device and a method for mounting a semiconductor device.

### BACKGROUND

A semiconductor chip having a flip chip structure suitable for fine-pitch electrodes has been developed because of needs for low-cost, high-density semiconductor devices. The term “flip chip structure” as used herein refers to a structure in which conductive bumps are arranged on electrodes of a semiconductor device.

After that, a plurality of methods for bonding semiconductor chips having a flip chip structure to boards have been proposed (see Japanese Laid-open Patent Publication No. 2002-170853). Among the methods is a bonding method in which solder is used as a contact material to bond pads on electrodes of a board to bumps on electrodes of a semiconductor chip having a flip chip structure.

The bonding method includes a solder-melting step in which heat treatment is performed. The heat treatment causes junctions between the electrodes of the board and the bumps of the semiconductor chip to be thermally deformed because of a difference in thermal expansion coefficient between the semiconductor chip, which is made of, for example, silicon or the like and the board, which is made of a glass-epoxy composite or the like. When the electrodes of the board and the bumps of the semiconductor chip are arranged at fine pitches and therefore the junctions have a reduced size and insufficient bonding strength, the junctions are often broken.

In order to decrease the temperature of heat treatment performed in solder-melting steps, the use of low-melting point solders has been investigated (Japanese Laid-open Patent Publication No. 2006-245186, Japanese Laid-open Patent Publication No. 2003-298056, and Japanese Laid-open Patent Publication No. 2001-274195). In an additional component-mounting step performed subsequently to the mounting of a semiconductor chip on a board, heat treatment is performed at a temperature higher than the melting point of a low-melting point solder. Therefore, solder on a bonding portion is re-melted by the heat treatment performed in the additional component-mounting step. When voids are present in an underfill material placed around the bonding portion, the melted solder flows into the voids. The melted solder causes electrical short circuits between electrodes adjacent to each other. Electrodes out of which solder flows have an insufficient amount of solder and therefore the bonding between electrodes of a board and bumps of a semiconductor chip may not be maintained in some cases.

### SUMMARY

According to one aspect of the embodiments, there is provided a method for mounting a semiconductor device includes a step of contacting a gold (Au) bump of a semiconductor chip with a tin-bismuth (Sn—Bi) solder and a step of heating the tin-bismuth (Sn—Bi) solder at a temperature which is not lower than the melting point thereof and which is not higher than 180° C. for 30 minutes or more.

According to another aspect of the embodiments, there is provided a method for mounting a semiconductor device on a board by flip chip bonding. The method includes providing a bump having a first metal on the semiconductor chip; supplying a solder having a second metal and a third metal on a conductive pad of the board; melting the solder; introducing the bump of the semiconductor chip into the melted solder; and forming an intermetallic compound between the first metal of the bump and at least one of the second and the third metal of the solder.

According to yet another aspect of the embodiments, there is provided a semiconductor device includes a board including a conductive pad thereon; a semiconductor chip including a bump having a first metal, the bump coupled to the conductive pad through a solder having a second metal and a third metal; and an intermetallic compound between the first metal of the bump and at least one of the second and the third metal of the solder.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIGS. 1A, 1B, 1C and 1D are illustrations of steps performed to form an electrode structure of a semiconductor chip and an electrode structure of a board, the steps being included in a method for achieving a structure mounting a semiconductor device according to a first embodiment;

FIGS. 2A, 2B, and 2C are illustrations of steps performed to form an electrode structure of a semiconductor chip and an electrode structure of a board, the steps being included in a method for achieving a structure mounting a semiconductor device according to a first embodiment;

FIG. 3 is a phase diagram for tin-bismuth (Sn—Bi) eutectic alloys;

FIGS. 4A, 4B, and 4C are illustrations of the steps performed to bond the electrode structure of the semiconductor chip to the electrode structure of the board;

FIGS. 5A and 5B are illustrations illustrating the bismuth (Bi) segregation layer-forming step;

FIGS. 6A and 6B are illustrations illustrating experiment data for the relationship between the formation of bismuth segregation layers and heat-treating conditions;

FIG. 7 is a graph illustrating results obtained by the thermal analysis of a bonding portion (an original metal bump portion and an original solder piece) after a bismuth (Bi) segregation layer-forming step;

FIGS. 8A, 8B, and 8C are illustrations of steps included in the method according to the second embodiment; and

FIGS. 9A, 9B, and 9C are illustrations illustrating a method for achieving a structure mounting a semiconductor device according to a third embodiment.

### DESCRIPTION OF EMBODIMENTS

The present invention covers modifications in design of embodiments below, the modifications being appreciated by those skilled in the art, rearrangements of elements described in the embodiments, and modifications obtained by replacing the elements with other elements having the same effects as those of the elements. The present invention is not limited to the embodiments.

### First Embodiment

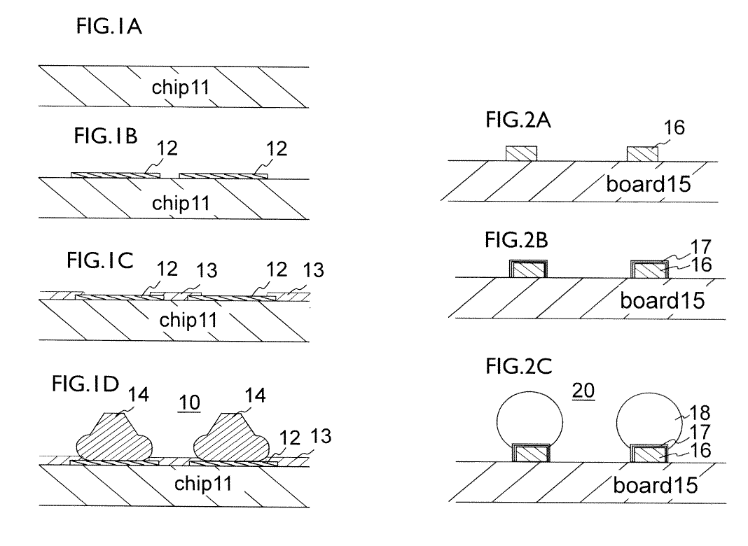

FIGS. 1A to 1D and 2A to 2C are illustrations of steps performed to form an electrode structure 10 of a semiconductor chip 11 and an electrode structure 20 of a board 15. The steps are included in a method for achieving a structure mounting a semiconductor device according to a first embodiment. The semiconductor device includes the board 15 and the semiconductor chip 11 mounted thereon.

FIGS. 1A to 1D each illustrate a cross section of a region surrounding electrodes 12 of the semiconductor chip 11 processed in a step of forming the electrode structure 10 of the semiconductor chip 11.

The electrode structure 10 of the semiconductor chip 11 is formed through a preparation step op1, an electrode-forming step op2, a windowing step op3, and a metal bump-forming step op4. The electrode structure 10 of the semiconductor chip 11 refers to a structure, including the electrodes 12, an insulating layer 13, and metal bumps 14, around the electrodes 12.

FIG. 1A is a sectional view of the semiconductor chip 11. The preparation step op1 is a step of preparing the semiconductor chip 11. The semiconductor chip 11 includes semiconductor elements and interconnects formed by a common semiconductor chip-manufacturing process and also includes insulating layers electrically insulating the interconnects from each other. The semiconductor chip 11 includes a semiconductor substrate made of silicon (Si) and may include a compound semiconductor substrate made of gallium arsenide or another semiconductor substrate.

FIG. 1B is a sectional view of the semiconductor chip 11 having the electrodes 12 thereon. The electrode-forming step op2 is a step of forming the electrodes 12. The electrodes 12 are connected to the interconnects of the semiconductor chip 11 and receive signals from the outside. In the electrode-forming step op2, a metal layer made of aluminum (Al) is formed on the insulating layer 13 and then processed into an electrode shape, whereby the electrodes 12 are formed.

FIG. 1C is a sectional view of the semiconductor chip 11 having the electrodes 12 and insulating layer 13 thereon, the insulating layer 13 being windowed. The windowing step op3 is a step of forming the insulating layer 13 over the electrodes 12 and the semiconductor chip 11 using an insulating organic material and then forming windows extending to the electrodes 12 in the insulating layer 13.

FIG. 1D is a sectional view of the semiconductor chip 11 having the metal bumps 14 thereabove. The metal bump-forming step op4 is a step of forming the metal bumps 14 in such a manner that metal wires made of gold (Au) are bonded to the electrodes 12 through the windows, metal balls are formed in the widows by squashing the metal wires, and portions extending from the metal balls are cut off.

After the metal bump-forming step op4 is finished, the electrode structure 10 of the semiconductor chip 11 is completed.

FIGS. 2A to 2C each illustrate a cross section of a region surrounding electrodes 16 of the board 15, which is in processing such that the electrode structure 20 of the board 15 is formed. The electrode structure 20 of the board 15 is formed through a preparation step op5, a metal coating-forming step op6, and a solder piece-forming step op7. The electrode structure 20 of the board 15 refers to a structure, including the electrodes 16, metal coatings 17, and solder pieces 18, around the electrodes 16.

FIG. 2A is a sectional view of the board 15. The preparation step op5 is a step of preparing the board 15. The board 15 includes insulating substrates, a surface wiring layer which includes the electrodes 16 and which is disposed at the top of the board 15, a wiring layer disposed between the insulating substrates, and via-hole interconnects which extend through the insulating substrates to connect the wiring layer to the surface wiring layer. The surface wiring layer and wiring layer of the board 15 are made of a metal material containing copper (Cu). The insulating substrates of the board 15 are made of a glass-epoxy resin and may be made of an insulating resin or a resin containing a material, such as carbon or invar, having high heat conductivity.

FIG. 2B is a sectional view of the board 15 with the metal coatings 17 disposed on the electrodes 16 arranged in the surface wiring layer. The metal coating-forming step op6 is a step of depositing the metal coatings 17 on the electrodes 16 by electroplating the electrodes 16. The electrodes 16 contain copper (Cu). The metal coatings 17 each include two layers: a nickel (Ni) layer and a gold (Au) layer disposed thereon. The reason why the nickel (Ni) layers are deposited on the electrodes 16, which contain copper (Cu), is to enhance the adhesion between the electrodes 16 and the gold (Au) layers. The reason why the gold (Au) layers are deposited on the nickel (Ni) layers is to allow the solder pieces 18, which are formed on the electrodes 16 and then melted as described below, to keep a good shape. The reason why such a good shape is kept is that the gold (Au) layers have surface properties (such as surface tension) suitable for the solder pieces 18.

FIG. 2C is a sectional view of the board 15 with the solder pieces 18 formed on the electrodes 16. The solder piece-forming step op7 is a step of forming the solder pieces 18 in such a manner that a mask having windows located on the electrodes 16 is formed on the board 15, a solder layer is deposited over the mask, and the mask is then stripped off. The solder pieces 18 are made of a eutectic alloy containing tin (Sn) and bismuth (Bi). The weight percentage of each of tin and bismuth in the solder pieces 18 is preferably set such that the eutectic alloy has a melting point (eutectic temperature) of 139° C. to 150° C. In order to allow the solder pieces 18, which are made of the eutectic alloy containing tin (Sn) and bismuth (Bi), to have a melting point (eutectic temperature) of 139° C., which is lowest, the weight percentage of bismuth (Bi) in the solder pieces 18 is preferably 57% with respect to tin (Sn). After the solder piece-forming step op7 is finished, the electrode structure 20 of the board 15 is completed. The solder piece-forming step op7 is not limited to the above and may be a step of transferring a solder paste to the metal bumps 14.

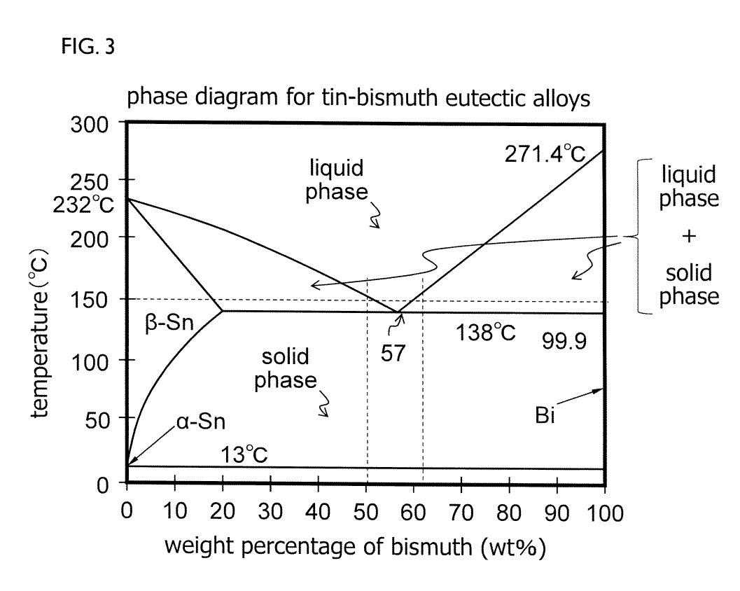

FIG. 3 illustrates a phase diagram for tin-bismuth (Sn—Bi) eutectic alloys. The horizontal axis of the phase diagram represents the weight percentage (weight percent) of bismuth (Bi). The vertical axis of the phase diagram represents the temperature (° C.). As illustrated in FIG. 2, the phase diagram illustrates that a tin-bismuth (Sn—Bi) eutectic alloy containing 0 weight percent bismuth has a melting point of 232° C. and the melting point decreases monotonically with an increase in the weight percentage of bismuth. When the weight percentage of bismuth is 57%, the melting point is about 132° C. Thereafter, the melting point increases with an increase in the weight percentage of bismuth. When the weight percentage of bismuth is 100%, the melting point is about 272° C.

From the phase diagram for the tin-bismuth (Sn—Bi) eutectic alloys illustrated in FIG. 2, a tin-bismuth (Sn—Bi) eutectic alloy having a melting point of 139° C. to 150° C. has a bismuth (Bi) weight percentage of about 50% to 63%.

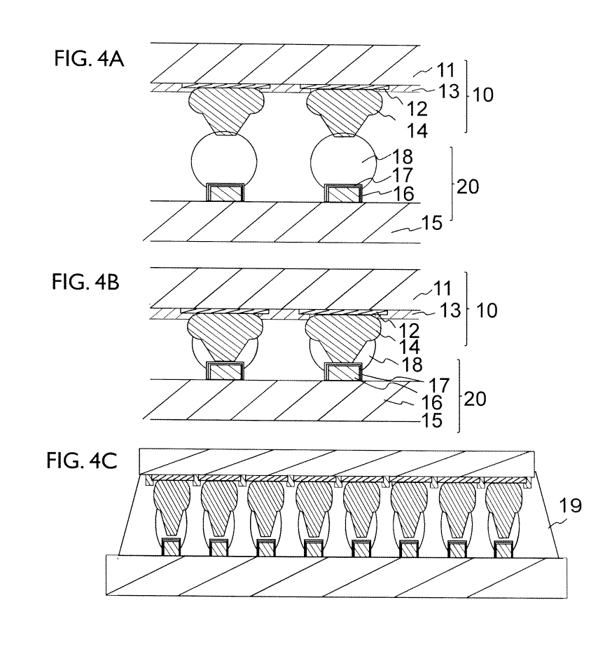

FIGS. 4A, 4B, and 4C illustrate steps performed to bond the electrode structure 10 of the semiconductor chip 11 to the electrode structure 20 of the board 15, the steps being included in the method for achieving the semiconductor device-mounting structure according to the first embodiment. FIGS. 4A to 4C are illustrations of these steps. These steps are a solder-melting step op8 of heating the solder pieces 18 in such a state that the metal bumps 14 of the semiconductor chip 11 are in contact with the solder pieces 18 of the board 15, a closely arranging step op9 of closely arranging the metal bumps 14 and the electrodes 16 of the board 15, and an underfill material-injecting step op10 of injecting an underfill material 19 between the semiconductor chip 11 and the board 15 and then curing the underfill material 19 to fix the semiconductor chip 11 to the board 15.

FIG. 4A is a sectional view illustrating a state that the electrode structure 20 of the board 15 is in contact face-to-face with the electrode structure 10 of the semiconductor chip 11.

The solder-melting step op8 is a step of heat-treating the solder pieces 18 in the state illustrated in FIG. 3B at a temperature at which the solder pieces 18 are melted. The solder pieces 18, which are made of the eutectic alloy, have a melting point (eutectic temperature) of 139° C. to 150° C.; hence, in the solder-melting step op8, the solder pieces 18 are preferably heat-treated at a temperature exceeding the melting point thereof.

FIG. 4B is a sectional view illustrating a state that the electrodes 16 and the metal bumps 14 are closely arranged with the solder pieces 18 melted.

The closely arranging step op9 is a step of closely arranging the electrodes 16 and the metal bumps 14 by reducing the distance between the board 15 and the semiconductor chip 11.

The closely arranging step op9 is performed in such a state that the temperature given by the solder-melting step op8 is hold. This allows the metal bumps 14 to enter the melted solder pieces 18, so that the tips of the metal bumps 14 approach the electrodes 16 of the board 15.

A jig of a mounting apparatus that supports the semiconductor chip 11 has a heat-retaining function and therefore the temperature given by the solder-melting step op8 is hold.

In order to closely arrange the electrodes 16 and the metal bumps 14, the jig of the mounting apparatus that supports the semiconductor chip 11 may be brought close to the board 15 and the weight of the semiconductor chip 11 and the weight of the jig may be used.

The tips of the metal bumps 14 are preferably spaced from the electrodes 16 at a distance of about 0 μm to 30 μm. This is because when the metal bumps 14 are spaced from the electrodes 16, the contact area between each of the metal bumps 14 and a corresponding one of the electrodes 16 is large and therefore the reaction of gold (Au) in the metal bumps 14 with tin (Sn) in the solder pieces 18 readily occurs to produce an intermetallic compound. The reason why the distance from the tips of the metal bumps 14 to the electrodes 16 is preferably up to about 30 μm is that the supply of tin (Sn) requested for a gold-tin (Au—Sn) intermetallic compound described below is suitable for the formation of the intermetallic compound. The board 15 and the semiconductor chip 11 are entirely cooled to a temperature not higher than the melting point of the solder pieces 18.

FIG. 4C is a sectional view illustrating a state that the underfill material 19 is disposed between the board 15 and the semiconductor chip 11.

The underfill material-injecting step op10 is a step of injecting the underfill material 19 between the board 15 and the semiconductor chip 11. In this step, the underfill material 19 is cured by heating. The underfill material 19 may be a heat-curable resin and is, for example, an epoxy resin. The underfill material 19 may contain insulating spherical filler.

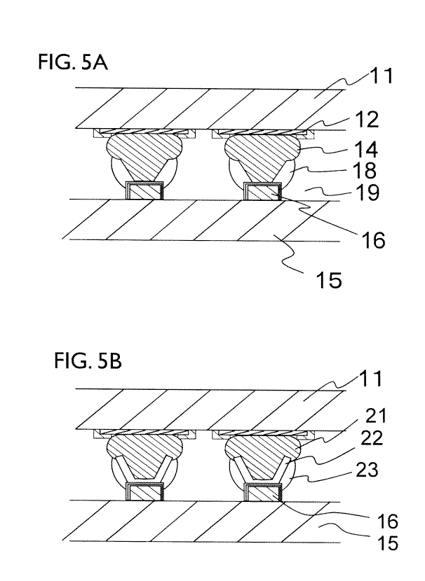

FIGS. 5A and 5B are illustrations illustrating the bismuth (Bi) segregation layer-forming step op11 included in the method for achieving the semiconductor device-mounting structure according to the first embodiment. A structure prepared by bonding the electrode structure 10 of the semiconductor chip 11 to the electrode structure 20 of the board 15 by the method for achieving the semiconductor device-mounting structure refers to a mounting structure.

FIG. 5A is a sectional view of a bonding portion of the semiconductor device in which the underfill material 19 is disposed between the board 15 and the semiconductor chip 11. In FIG. 5B, the semiconductor chip 11, the electrodes 12, the metal bumps 14, the board 15, the electrodes 16, the metal coatings 17, the solder pieces 18, and the underfill material 19 are illustrated.

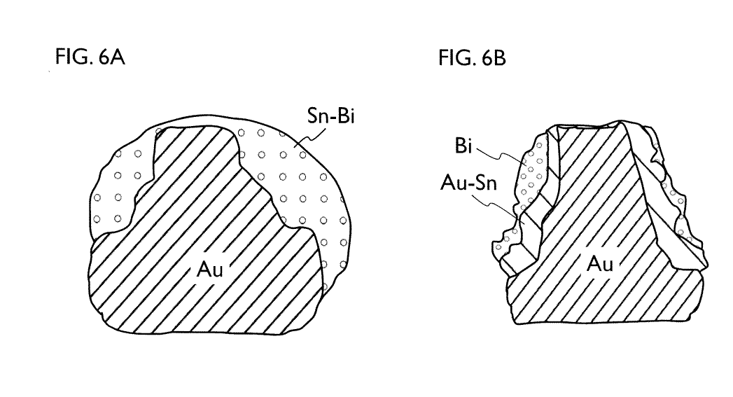

The bismuth (Bi) segregation layer-forming step op11 is a step of heat-treating the board 15 and the semiconductor chip 11 under predetermined conditions. Preferred heat-treating conditions include a combination of about 150° C. and 60 minutes or more and a combination of about 180° C. and 30 minutes or more. That is, a tin-bismuth (Sn—Bi) solder is preferably heated at a temperature which is not lower than the melting point thereof and which is not higher than 180° C. for 30 minutes or more. Heat-treating conditions are described below in detail with reference to FIG. 6A and FIG. 6B. The board 15 and the semiconductor chip 11, which are in a state illustrated in FIG. 3B, are subjected to the bismuth (Bi) segregation layer-forming step op11, whereby a state illustrated in FIG. 5D is achieved.

FIG. 5B is a sectional view of a bonding portion including bismuth segregation layers 23 formed by performing the bismuth (Bi) segregation layer-forming step op11. FIG. 5B illustrates that metal bump portions 21 are formed in the original metal bumps 14, gold-tin (Au—Sn) intermetallic compound layers 22 are formed on the metal bump portions 21, and the bismuth segregation layers 23 are formed in the original solder pieces 18 through the bismuth (Bi) segregation layer-forming step op11.

The underfill material 19 is cured by heat treatment at about 150° C. for 60 minutes or more or at 180° C. for 30 minutes or more.

The metal bump portions 21 are made of gold (Au). The gold-tin (Au—Sn) intermetallic compound layers 22 are made of the gold-tin intermetallic compound and have a tin weight percentage of 80% or more. The bismuth (Bi) segregation layers 23 have a bismuth (Bi) weight percentage of 99% or more. The formation of the gold-tin (Au—Sn) intermetallic compound layers 22 and the bismuth segregation layers 23 in the bonding portion through the bismuth (Bi) segregation layer-forming step op11 is verified below with reference to FIGS. 5A, 5B and 6A, 6B.

FIGS. 6A and 6B are illustrations illustrating experiment data for the relationship between the formation of the bismuth segregation layers 23 and heat-treating conditions.

FIG. 6A illustrates results obtained by observing a solder piece 18 and a metal bumps 14 in cross section, the solder piece 18 and the metal bump 14 being heat-treated at 140° C. for ten seconds or less in the bismuth (Bi) segregation layer-forming step op11. With reference to FIG. 6A, the metal bump 14, which is made of gold (Au), and the solder piece 18, which is made of tin-bismuth (Sn—Bi), are free from transformation. This is probably because although the solder piece 18 is melted at about 140° C., the reaction of tin with gold in the metal bump 14 does not proceed at about 140° C.

FIG. 6B illustrates results obtained by observing a bonding portion including a solder piece 18 and a metal bump 14 in cross section, the solder piece 18 and the metal bump 14 being heat-treated at 150° C. for 60 minutes or more in the bismuth (Bi) segregation layer-forming step op11. With reference to FIG. 6B, a metal bump portion 21 is present in the original metal bump 14, an intermetallic compound layer (a gold-tin (Au—Sn) intermetallic compound layer 22 described below) is present on the metal bump portion 21, and a layer (a bismuth segregation layer 23 described below) different from the solder piece 18 is present in the original solder piece 18. Therefore, the reaction of tin in the solder piece 18 with gold in the metal bump 14 probably proceeds at about 150° C. The inventor has observed that a bismuth segregation layer similar to that illustrated in FIG. 6B is formed in a solder piece 18 by heat treatment at 180° C. for 30 minutes or more in a bismuth (Bi) segregation layer-forming step.

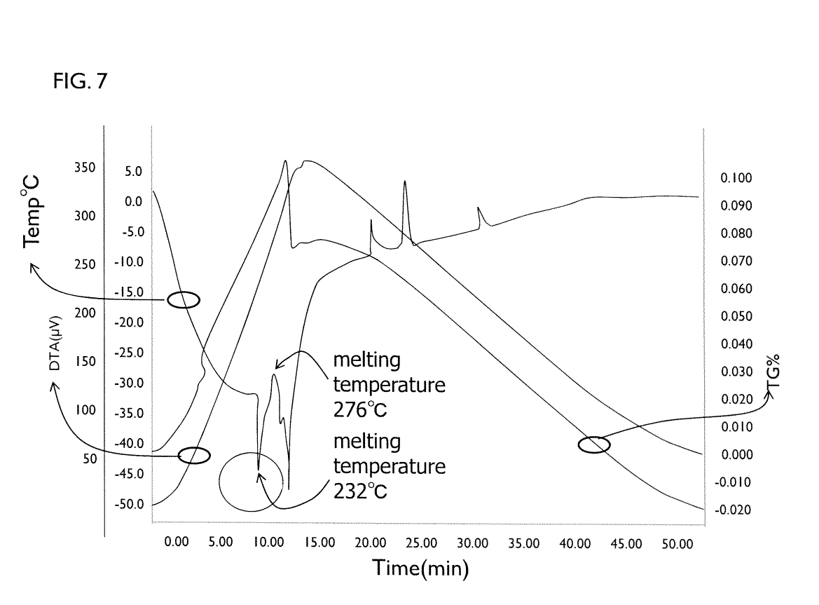

FIG. 7 is a graph illustrating results obtained by the thermal analysis of a bonding portion (an original metal bump portion 14 and an original solder piece 18) heat-treated at 150° C. for 60 minutes or more after the bismuth (Bi) segregation layer-forming step op11.

In this graph, the abscissa represents the heat-treating time (minutes), the right ordinate represents TG (thermo-gravimetry (%), a change in weight by heating), the first left ordinate represents the temperature (° C.), and the second left ordinate represents DTA (differential thermal analysis (μV)).

Results obtained by DTA illustrate that the bonding portion (the original metal bump portion 14 and the original solder piece 18) has a first melting temperature of about 232° C., a second melting temperature of about 276° C., and a third melting temperature of about 295° C. That is, the bonding portion (the original metal bump portion 14 and the original solder piece 18) has significantly increased melting temperatures in consideration that the solder piece 18 has a melting temperature of 139° C. to 150° C.

The melting point of gold (Au) is about 1,000° C., that of the gold-tin (Au—Sn) intermetallic compound is about 300° C., that of bismuth (Bi) is about 270° C., and that of tin (Sn) is about 230° C. Since the results obtained by DTA illustrate that the bonding portion has a first melting temperature of about 232° C. and a second melting temperature of about 276° C., it is clear that tin (Sn) and bismuth (Bi) are separated from each other. Furthermore, it is clear that the gold-tin (Au—Sn) intermetallic compound is produced.

In the bonding portion (the original metal bump portion 14 and the original solder piece 18), tin (Sn) in the solder piece 18 migrates toward the metal bump 14 to form an intermetallic compound together with gold (Au) in the metal bump 14. This probably allows a gold-tin (Au—Sn) intermetallic compound layer 22 to be formed on the metal bump 14 and also allows tin (Sn) to concentrate near the gold-tin (Au—Sn) intermetallic compound layer 22. A core portion of the original metal bump 14 is probably converted into a metal bump portion 21. Furthermore, bismuth (Bi) in the solder piece 18 is squeezed onto a surface of the solder piece 18, whereby a bismuth segregation layer 23 is probably formed near the surface of the solder piece 18.

From the above, the heat treatment of the board 15 and the semiconductor chip 11 at a temperature of 150° C. to 180° C. for 30 minutes or more in the bismuth (Bi) segregation layer-forming step op11 allows the metal bump portion 21, the gold-tin (Au—Sn) intermetallic compound layer 22, and the bismuth segregation layer 23 to be formed in the bonding portion. Analysis for melting temperature estimates that the gold-tin (Au—Sn) intermetallic compound layer 22 has a tin weight percentage of 80% or more and the bismuth segregation layer 23 has a bismuth (Bi) weight percentage of 99% or more.

From the above, the method for achieving the semiconductor device-mounting structure according to the first embodiment includes a step of forming the electrodes 12 connected to the semiconductor chip 11 and the metal bumps 14 which are connected to the electrodes 12 and which are made of gold, a step of depositing the electrodes 16 on the board 15 and the solder pieces 18 containing tin (Sn) and bismuth (Bi) on the electrodes 16, a step of melting the solder pieces 18, a step of closely arranging the metal bumps 14 and the electrodes 16 by inserting the metal bumps 14 in the melted solder pieces 18, a step of injecting the underfill material 19 between the board 15 and the semiconductor chip 11, a step of curing the underfill material 19, and a step of performing heat treatment under such conditions that an intermetallic compound is formed from gold in the metal bumps 14 and tin (Sn) in the solder pieces 18.

In the method for achieving the semiconductor device-mounting structure according to the first embodiment, the distance between each of the metal bumps 14 and a corresponding one of the electrodes 16 is adjusted to 30 μm or less in the step of closely arranging the metal bumps 14 and the electrodes 16 by inserting the metal bumps 14 in the melted solder pieces 18.

In the method for achieving the semiconductor device-mounting structure according to the first embodiment, the ratio of the weight of tin (Sn) to the weight of bismuth (Bi) is adjusted such that the solder pieces 18, which contain tin (Sn) and bismuth (Bi), has a melting point of 150° C. or less.

In the method for achieving the semiconductor device-mounting structure according to the first embodiment, the melting point of the solder pieces 18 exceeds 230° C. owing to heat treatment in the step of performing heat treatment under such conditions that the intermetallic compound is formed from gold in the metal bumps 14 and tin (Sn) in the solder pieces 18.

The step of curing the underfill material 19 and the step of performing heat treatment under such conditions that the intermetallic compound is formed from gold in the metal bumps 14 and tin (Sn) in the solder pieces 18 need not be separately performed and may be combined into a single heat-treating step.

The semiconductor device-mounting structure according to the first embodiment includes the electrodes 12 connected to the semiconductor chip 11, the metal bumps 14 made of gold, the electrodes 16 connected to the board 15, the solder pieces 18 which are connected to the electrodes 16 and which contain tin (Sn) and bismuth (Bi), intermetallic compound layers which are disposed between the solder pieces 18 and the metal bump portions 21 and which contain gold and tin, and the bismuth segregation layers 23 disposed in the solder pieces 18.

The formation of the intermetallic compound from gold in the metal bumps 14 and tin (Sn) in the solder pieces 18 causes the migration of most of tin (Sn) in the solder pieces 18 into the metal bumps 14. This convert the metal bumps 14 into the metal bump portions 21 and the gold-tin (Au—Sn) intermetallic compound layers 22. In the solder pieces 18, tin (Sn) and bismuth (Bi) are not in an alloy state. Therefore, after the semiconductor chip 11 is mounted on the board 15, the bonding portions (the metal bumps 14 and the solder pieces 18) have an increased melting temperature. In particular, the board 15 and the semiconductor chip 11 are bonded to each other at a temperature of 150° C. to 180° C. in the case of bonding the electrode structures 10 and 20 to each other. This is because the solder pieces 18 have a melting temperature of 150° C. or lower. However, the mounting structure is not melted at a temperature of lower than 230° C.

Accordingly, a mounting structure between the board 15 and the semiconductor chip 11 is not melted by heat treatment performed to mount another component on the board 15 subsequently to the termination of the mounting of the semiconductor chip 11 on the board 15. Therefore, adjacent electrodes are prevented from being electrically short-circuited by the melting of the solder pieces 18. The bismuth segregation layers 23 formed in the solder pieces 18 are not melted when another component is mounted on the board 15; hence, the bonding between the board 15 and the semiconductor chip 11 is maintained.

### Second Embodiment

In the first embodiment, after the underfill material 19 is injected between the semiconductor chip 11 and the board 15, the bismuth (Bi) segregation layer-forming step op11 is performed. In a second embodiment, after a step of closely arranging the metal bumps 14 and the electrodes 16 of the board 15 is performed, the bismuth (Bi) segregation layer-forming step op11 and then a step of injecting the underfill material 19 between the semiconductor chip 11 and the board 15 may be performed.

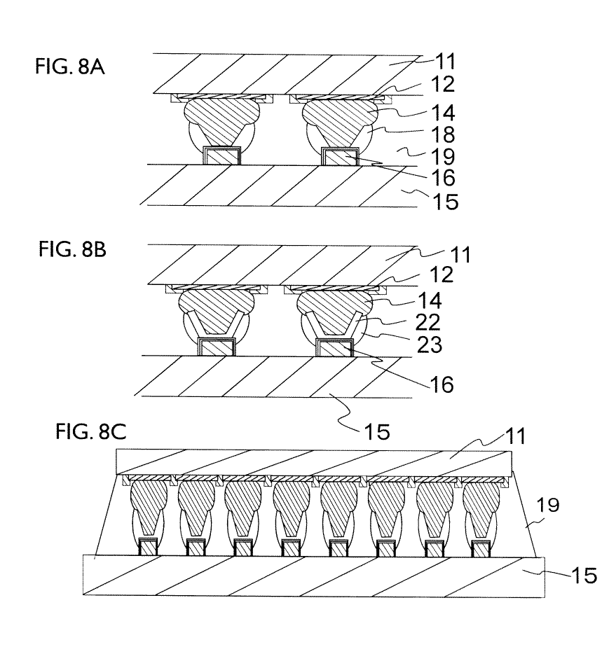

FIGS. 8A, 8B, and 8C are illustrations of steps included in the method for achieving a structure mounting a semiconductor device according to the second embodiment. In the method for achieving the semiconductor device-mounting structure according to the second embodiment, a closely arranging step op9 of closely arranging metal bumps 14 and electrodes 16 of a board 15 and steps prior thereto are substantially the same as those described in the first embodiment, these steps being performed to bond an electrode structure 10 of a semiconductor chip 11 to an electrode structure 20 of the board 15.

FIG. 8A is an illustration illustrating the state of the semiconductor chip 11 and the electrodes 16 of the board 15 just after the termination of a closely arranging step op9 of closely arranging the metal bumps 14 and the electrodes 16 of the board 15. In FIG. 8A, the semiconductor chip 11, electrodes 12, the metal bumps 14, solder pieces 18, an underfill material 19, the electrodes 16, and the board 15 are illustrated.

In the method for achieving the semiconductor device-mounting structure according to the second embodiment, a bismuth (Bi) segregation layer-forming step op11 is performed subsequently to the closely arranging step op9.

FIG. 8B is an illustration illustrating the state of the semiconductor chip 11 and the board 15 just after the termination of the bismuth (Bi) segregation layer-forming step op11. In FIG. 8B, the semiconductor chip 11, the electrodes 12, the metal bumps 14, intermetallic compound layers 22, bismuth segregation layers 23, the electrodes 16, and the board 15 are illustrated.

In the method for achieving the semiconductor device-mounting structure according to the second embodiment, a step op10 of injecting the underfill material 19 between the semiconductor chip 11 and the board 15 is performed subsequently to the bismuth (Bi) segregation layer-forming step op11, whereby the mounting structure is completed.

FIG. 8C is an illustration illustrating the state of the semiconductor chip 11 and the board 15 just after the termination of the step op10 of injecting the underfill material 19 between the semiconductor chip 11 and the board 15. In FIG. 8C, the semiconductor chip 11, the underfill material 19, and the board 15 are illustrated.

As described above, substantially the same mounting structure as that described in the first embodiment may be obtained by the method for achieving the semiconductor device-mounting structure according to the second embodiment.

### Third Embodiment

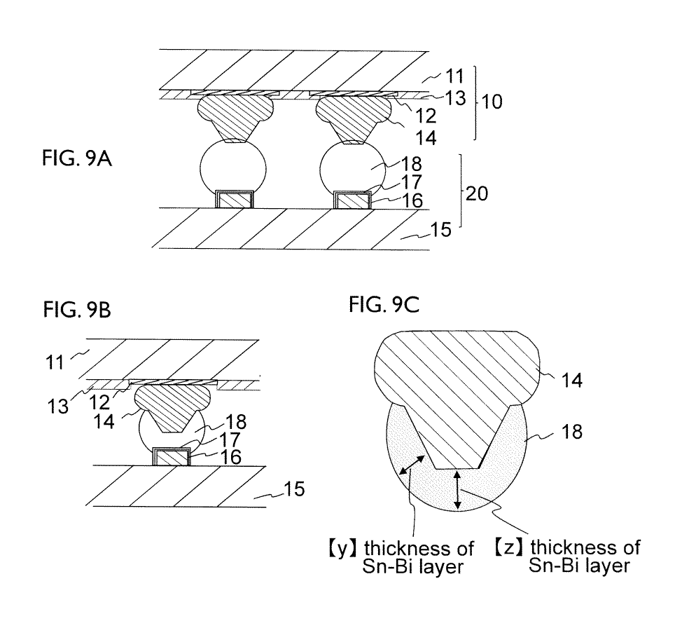

FIGS. 9A, 9B and 9c are illustrations illustrating a method for achieving a structure mounting a semiconductor device according to a third embodiment. In the method for achieving the semiconductor device-mounting structure according to the third embodiment, a solder-melting step op8 and steps prior thereto are substantially the same as those described in the first embodiment, these steps being performed to bond an electrode structure 10 of a semiconductor chip 11 to an electrode structure 20 of a board 15.

FIG. 9A is a sectional view illustrating the state after the termination of the solder-melting step op8, in which heat treatment is performed at a temperature at which solder pieces 18 are melted. A heat-treating temperature at which the solder pieces 18 are melted is 139° C. to 150° C.

FIG. 9B is a sectional view illustrating the state after the termination of a closely arranging step. FIG. 9C is a magnification illustrating the electrode structure. The closely arranging step is a step of closely arranging the board 15 and the semiconductor chip 11. The closely arranging step is different from that described in the first embodiment in that the distance between the periphery of each of the solder pieces 18 and the periphery of a corresponding one of metal bumps 14 is adjusted to about 30 μm and the weight of gold in each of the metal bumps 14 excluding bases is adjusted to 30% or less of the weight of a corresponding one of the solder pieces 18. In order to adjust the distance between the periphery of each of the solder pieces 18 and the periphery of a corresponding one of the metal bumps 14 to about 30 μm, the distance between the tip of each of the electrodes 16 and the tip of a corresponding one of the metal bumps 14 is adjusted to about 30 μm in the closely arranging step.

In the closely arranging step, the adjustment of distance and the adjustment of weight percentage are performed by adjusting the distance between the tip of each of the electrodes 16 and the tip of a corresponding one of the metal bumps 14. The adjustment of distance and the adjustment of weight percentage may be performed in a step of forming the electrode structure 10 of the semiconductor chip 11 and a step of forming the electrode structure 20 of the board 15 in such a manner that the shape of the metal bumps 14 or the shape of the solder pieces 18 is adjusted.

The adjustment of the weight of gold in each of the metal bumps 14 excluding the bases to 30% or less of the weight of a corresponding one of the solder pieces 18 provides an advantage below. Since the solder pieces 18 have a melting temperature of 139° C. to 150° C., the range of the weight percentage of tin (Sn) in each solder piece 18 is consistent with the melting temperature thereof. When the weight of gold (Au) in each of the metal bumps 14 excluding the bases is 30% or less of the weight of a corresponding one of the solder pieces 18, the ratio of the weight of gold (Au) in each of the metal bumps 14 excluding the bases to the weight of tin (Sn) in a corresponding one of the solder pieces 18 is within a certain range. This allows most of tin (Sn) in the solder pieces 18 to form an intermetallic compound together with gold (Au); hence, bismuth segregation layers are readily formed in the original solder pieces 18. In the solder pieces 18, tin (Sn) and bismuth (Bi) are not in an alloy state. Therefore, bonding portions (the original solder pieces 18 and the metal bumps 14) have an increased melting temperature.

The reason why the distance between the tip of each of the electrodes 16 and the tip of a corresponding one of the metal bumps 14 is adjusted to about 30 μm is that the range that tin (Sn) may reach gold (Au) in the metal bumps 14 owing to thermal diffusion is about 30 μm. If tin (Sn) may not reach gold (Au) therein, the intermetallic compound may not be formed.

The method for achieving the semiconductor device-mounting structure according to the third embodiment is characterized in that the distance between the tip of each of the electrodes 16 and the tip of a corresponding one of the metal bumps 14 is adjusted to about 30 μm in the closely arranging step of the method for achieving the semiconductor device-mounting structure according to the first embodiment. Therefore, the weight of gold in each of the metal bumps 14 is 30% or less of the weight of a corresponding one of the solder pieces 18 and the distance between the periphery of each of the solder pieces 18 and the periphery of a corresponding one of the metal bumps 14 is about 30 μm.

Since most of tin (Sn) in the solder pieces 18 migrates into the metal bumps 14 because of the formation of the intermetallic compound from gold in the metal bumps 14 and tin (Sn), tin (Sn) and bismuth (Bi) in the solder pieces 18 are not in an alloy state. This allows the bonding portions (the metal bumps 14 and the solder pieces 18) to have an increased melting temperature.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a depicting of the superiority and inferiority of the invention. Although the embodiments of the present invention have been described in detail, it should be understood that the various changes, substitutions, and alterations could be made hereto without departing from the spirit and scope of the invention.

1. A method for mounting a semiconductor device by mounting a semiconductor chip on a board by flip chip bonding, comprising:
contacting an Au bump of the semiconductor chip with a Sn—Bi solder; and
heating the Sn—Bi solder at a temperature which is not lower than the melting point thereof and which is not higher than 180° C. for 30 minutes or more.

2. The method according to claim 1, further comprising:
injecting a underfill material between the board and the semiconductor chip,
wherein the heating of the Sn—Bi solder and the curing of the underfill material are simultaneously performed.

3. The method according to claim 1, wherein the distance between the Au bump and the board is maintained at 30 μm or less when the Sn—Bi solder is heated.

4. A method for mounting a semiconductor device by mounting a semiconductor chip on a board by flip chip bonding, comprising:
providing a bump having a first metal on the semiconductor chip;
supplying a solder having a second metal and a third metal on a conductive pad of the board;
melting the solder;
introducing the bump of the semiconductor chip into the melted solder; and
forming an intermetallic compound between the first metal of the bump and at least one of the second and the third metal of the solder.

5. The method according to claim 4, wherein the intermetallic compound includes Au as the first metal and Sn as the second metal.

6. The method according to claim 4, wherein the second and third metal of the solder have a weight percent ratio such that a melting temperature of the solder is equal or lower than 150 degrees Celsius.

7. The method according to claim 4, further comprising forming a segregation layer having Bismuth as the third metal at a given heat treatment.

8. The method according to claim 4, further comprising:
disposing an underfill material between the semiconductor chip and the board; and
curing the underfill material.

9. The method according to claim 4, wherein the bump of the semiconductor chip is introduced into the melted solder such that the distance between the bump and the conductive pad is 30 μm or less.

10. A semiconductor device comprising:
a board including a conductive pad thereon;
a semiconductor chip including a bump having a first metal, the bump coupled to the conductive pad through a solder having a second metal and a third metal; and
an intermetallic compound between the first metal of the bump and at least one of the second and the third metal of the solder.

11. The semiconductor device according to claim 10, further comprising a segregation layer formed of the third metal in the solder.

12. The semiconductor device according to claim 10, wherein the intermetallic compound includes Au as the first metal and Sn as the second metal.

13. The semiconductor device according to claim 11, wherein the segregation layer having Bismuth as the third metal.

14. The semiconductor device according to claim 10, further comprising an underfill material disposed between the semiconductor chip and the board.
